(19) United States
(12) Patent Application Publication
(10) Pub. No.: US 2026/0322313 A1
(43) Pub. Date: Oct. 15, 2026

(54) ROOF STRUCTURE HAVING PHOTOVOLTAIC MODULES

(71) Applicant: mygreen Holding GmbH, Dortmund (DE)

(72) Inventor: Tim BRÖCKELMANN, Dortmund (DE)

(21) Appl. No.: 19/104,677

(22) PCT Filed: Aug. 4, 2023
(86) PCT No.: PCT/EP2023/071736

§ 371 Date: Feb. 18, 2025

(30) Foreign Application Priority Data
Aug. 18, 2022 (DE) 10 2022 120 931.8

(51) Int. Cl. H02S 20/23; E04D 13/04

(52) U.S. Cl. CPC H02S 20/23; E04D 13/0445; E04D 2013/045

(57) ABSTRACT

The invention relates to a roof structure 10 and a method of manufacturing the same. The roof structure 10 comprises a plurality of parallel supporting gutters 20, each formed from aligned supporting gutter sections 22, wherein ends of the supporting gutter sections 22 are arranged to overlap each other. Panel elements 24, 124 are each arranged between two supporting gutters 20 and rest on support areas 34 of the supporting gutter sections 22. The panel elements 24, 124 are arranged to overlap in the longitudinal direction of the supporting gutters 20. The panel elements 24 are transparent covers and photovoltaic modules 28 are arranged below the panel elements 24 and/or the panel elements 124 are photovoltaic modules.

### CROSS-REFERENCE TO RELATED APPLICATIONS

This application is the U.S. national phase under 35 U.S.C. 371 of International Application No. PCT/EP2023/071736 filed Aug. 4, 2023, which claims priority to German Patent Application No. 10 2022 120 931.8 filed Aug. 18, 2022, the disclosures of which are incorporated herein by reference in their entireties.

### FIELD OF THE INVENTION

The invention relates to a roof structure with photovoltaic modules and a method for manufacturing such a roof structure.

### BACKGROUND OF THE INVENTION

The term “roof structure” is used here generally for the arrangement of building elements in the roof region of a building. In this context, the invention relates primarily to the roofing or outer surface of the roof and the (supporting) structure immediately below it, and less to the supporting structure of the roof.

A well-known structure for sloping house roofs comprises roof boarding, usually supported by rafters, and roofing supported by roof battens, traditionally made of overlapping roofing tiles. This creates a closed cover that is impermeable to weather influences such as rain and wind.

Various superstructures are known for utilizing solar radiation on the roof surface, such as solar thermal systems and photovoltaic systems. Traditionally, these are attached to the roof above the roofing with adapted support systems. Proposals have also already been made as to how elements for utilizing solar radiation on the roof surface, in particular photovoltaic modules, can be integrated into the roof structure.

DE 10034655 A1 describes a device for utilizing solar energy in which the covering of a roof is changed in such a way that a free flow channel is created between two layers through which air heated by solar energy flows. This is achieved by double covering the roof. The roofing facing the sun consists of glass roofing tiles. For the simultaneous generation of thermal energy and electrical energy, a radiation-absorbing layer can be designed as a photovoltaic layer.

WO 2019/168536 A1 describes the manufacture of photovoltaic structures and, in particular, photovoltaic roofing tiles. Solar cells are encapsulated under glass covers. Photovoltaic roofing tiles can be arranged in an overlapping manner and connected laterally by spacers. The spacers can have a groove on the top side that forms a visible gap between the roofing tiles.

DE 10 2008 026 505 A1 describes a solar module for a roof covering of a building roof with a photovoltaically active layer for transforming solar radiation into electrical energy, in which the thermal resistance of the solar module to a cooling medium on the underside of the photovoltaically active layer is reduced.

CH 703 472 A1 discloses a hybrid collector comprising a photovoltaic module and a first and second heat exchanger chamber. The first heat exchanger chamber has connections for the passage of a first heat transfer medium, which is in thermally conductive connection with the photovoltaic module. The second heat exchanger chamber has connections for the passage of a second heat transfer medium. This enables the photovoltaic module to be cooled in different ways. There are particular advantages in combination with a combined heat pump, which can extract heat from both air and a liquid heat transfer medium.

EP3923468 A1 describes a method for increasing the energy yield of an already installed solar power plant with a first solar panel that absorbs sunlight in a first frequency band. A semi-transparent second solar panel, which absorbs light in a second frequency band, is mounted on the first solar panel and connected to power electronics comprising at least one solar inverter. The second solar panel allows at least part of the light in the first frequency band to pass through.

### SUMMARY OF THE INVENTION

It can be regarded as an object to propose a roof structure for the integration of photovoltaic modules, with which a particularly efficient use of solar radiation on the roof surface is made possible with a simple structure.

The object is solved by a roof structure and a method. Dependent claims relate to advantageous embodiments of the invention.

The roof structure according to the invention has parallel supporting gutters and overlapping panel elements resting on them. Preferably, the panel elements form the upper end of the roof cladding, i.e. they are exposed without any further cover arranged above them.

The supporting gutters have a gutter shape with support areas for the panel elements, preferably with flat support areas on which the panel elements advantageously rest over their entire length, either directly or preferably with a seal in between. The support areas are preferably located on opposite sides of the supporting gutters.

The panel elements can be transparent covers, e.g. made of glass, in which case photovoltaic modules are arranged below the panel elements, preferably at a distance from the panel elements. In an alternative, preferred embodiment, the panel elements themselves can be photovoltaic modules. The two possible embodiments can also be combined if (partially or completely) transparent photovoltaic modules are used as panel elements. A possible embodiment is one in which a space protected by the transparent covers is formed below the panel elements, in which one or more photovoltaic modules are arranged. A preferred embodiment is one in which the panel elements themselves are photovoltaic modules, but a closed interior space is nevertheless formed underneath.

According to the invention, the supporting gutters are constructed from aligned supporting gutter sections, with the ends of the supporting gutter sections overlapping one another.

The overlapping arrangement of the supporting gutter sections at the ends results in a stepped arrangement that holds and supports the overlapping panel elements and, in particular, enables full-surface contact and sealing on the supporting gutters. At the same time, the overlapping arrangement of the supporting gutter sections enables a firm connection and straight, flush alignment due to the interlocking of the respective ends.

The supporting gutter sections are preferably profiles of a continuously uniform shape, preferably made of metal, e.g. aluminum or steel. Drawn profiles, (extruded) pressed profiles, rolled profiles or similar can be used; sheet metal profiles bent in a press bench are preferred. Preferably, the supporting gutter sections are at least essentially the same length (i.e. with a maximum deviation of +/−15%), although there may also be greater deviations, particularly at the ends of the supporting gutters. The length of the supporting gutter sections can be, for example, 30-200 cm, preferably 40-120 cm, particularly preferably 50-100 cm. The dimensions determine the length of the panel elements (measured in the direction of the roof slope); the above-mentioned length ranges have proven to be useful here, although it is also possible to deviate from this for different formats of panel elements. The overlap section, in which the front end of an upper supporting gutter section is arranged to engage in the rear end of a lower supporting gutter section, preferably has a smaller length relative to the lower and/or upper supporting gutter section of less than 25%, preferably 15% or less, preferably 10% or less. In fact, even a small overlap of, for example, at least one centimeter is sufficient to achieve the desired stepped arrangement; an overlap length of, for example, 4-12 cm is preferred.

The panel elements rest on the supporting gutters and are preferably also secured there against displacement and lifting. In principle, they can be secured to the supporting gutters in various ways, e.g. by form-fit mounting, screwing, clamping, bonding or the like. According to a preferred further development of the invention, retainers are arranged on the panel elements and connected to the supporting gutters. The panel elements are thus held from at least two opposite sides, namely on the underside by bearing against the support areas and on the upper side by the retainers. The retainers can, for example, be designed as flat elements such as plates, or preferably have an elongated shape and extend longitudinally over the panel elements, preferably over their entire length. The retainers can comprise an angle fold that embraces an edge of a panel element. Preferably, the retainers are arranged at the edge of the panel elements, e.g. in the area of their corners. The retainers can have folds at the ends, with which aligned retainers engage with each other. For example, an upper fold can be formed at an upper end, preferably directed upwards A lower fold can be formed at an opposite lower end, preferably directed downwards. The folds can interlock. One or both folds can be provided to rest against a lower edge of a panel element in order to support it against slipping. The retainers are preferably made of metal. A flexible intermediate layer, e.g. a sealing material, is preferably arranged between the retainers and the panel elements in order to enable the forces to be distributed over the contact surface and to avoid the risk of damage to the panel elements.

The connection of the retainers to the supporting gutters can be made, for example, by a web, a wall or—preferably—by a tension rod, in particular a threaded bolt. Preferably, a retainer can be arranged in such a way that it overlaps two adjacent panel elements and can thus fix both panel elements at the same time.

In principle, it is possible to arrange the retainers in the area where two supporting gutter sections overlap and to connect them there to the supporting gutter, in particular to the upper of the overlapping supporting gutter sections. Preferably, however, the retainers are arranged adjacent to, but advantageously outside, the area of the overlap of two supporting gutter sections and are connected to the supporting gutter there. The connection is preferably formed with the lower of the overlapping supporting gutter sections, e.g. on a bar attached to opposite side walls. An adjacent arrangement is understood to mean that the retainer and/or a fastening element for this purpose (such as a bolt or a screw) is arranged in the longitudinal direction of the supporting gutter directly in front of the overlap area or at a small distance (measured from the respective center of the retainer or fastening element to the edge of the adjacent overlap area) of, for example, less than 10% of the length of the lower supporting gutter section, preferably less than 5%, particularly preferably 3% or less. While it is possible to provide an element such as a rod that penetrates the bottom of the supporting gutter sections for fastening the retainer, the fastening preferably does not penetrate the wall of the supporting gutter sections in order to maintain the tightness.

In principle, the supporting gutter sections can have different cross-sectional shapes, e.g. V-shaped. For the overlapping arrangement, stackability is required at least in the overlapping area, but this can also be achieved by widening if necessary. While the supporting gutter sections can thus be shaped differently in the overlap area, for example, than over the rest of their length, they preferably have the same cross-sectional shape over their entire length, which is then preferably stackable. A trapezoidal cross-sectional shape of the supporting gutter sections is particularly preferred, i.e. a straight base from which straight side walls extend at oblique, outwardly directed angles. The cross-sectional shape is preferably symmetrical, so that the angles are the same on both sides. In a trapezoidal shape, the angles are more than 90° and are preferably in the range of 95°-130°, more preferably 100-120°, particularly preferably around 110° (+/−5°). Although these shapes have proven to be particularly suitable, other designs may be possible. The support areas can also preferably extend from the side walls as outwardly directed folds, preferably parallel to the floor. The trapezoidal shape is particularly suitable, as the supporting gutter sections formed can be produced cheaply and precisely, have good stability and, in particular, the supporting gutter sections can be easily arranged in a nested manner to produce the overlap. The straight contact surfaces on the walls and floor can be easily sealed against each other and/or fastened together if required.

The arrangement of the panel elements and the supporting gutter sections is preferably such that a closed, preferably sealed interior space is formed below the panel elements. For this purpose, it is preferable that the panel elements sealingly terminate with the support areas of the supporting gutter sections, e.g. by means of precisely fitting flat contact or preferably by means of an interposed seal, e.g. made of flexible sealing material. The panel elements are also preferably arranged to seal against each other in the overlapping area, here too by means of precisely fitting contact or—preferably—by means of interposed sealing elements made of flexible sealing material. In this way, the interior space can be sealed against the upper side, preferably with a seal at least against splash water, particularly preferably even at least essentially airtight or at least windtight.

Such a seal firstly ensures that the roof is sealed against weather influences, e.g. wind and rain, but also allows a controlled air flow in the interior space. The air in the sealed interior space heats up when the roof is exposed to solar radiation, especially when the sun shines through transparent covers. By selectively directing the air in the interior space, it is possible to dissipate the heat, e.g. to use it for heating purposes or similar. Another important aspect of air guidance is the setting of a favorable temperature range in the interior space for the function of the photovoltaic modules. By dissipating warm air, the photovoltaic modules, which are either—preferably—arranged as panel elements as part of the enclosure of the interior space or in the interior space, are cooled in the event of strong solar radiation, so that overheating can be avoided and the photovoltaic modules can be operated efficiently in a favorable temperature range.

According to one embodiment, tubes can be provided for air guidance. The tubes can also be part of the supporting structure for the supporting gutters. For example, the supporting gutters can be mounted on cross tubes and the cross tubes can have openings on the upper side for the supply and removal of air from the interior space. For example, a number of parallel cross tubes can be provided, each of which is alternately connected for the supply and removal of air from the interior space in order to enable the circulation and continuous removal of heated air. Alternatively, the air guidance can be carried out by other forms of lines such as air ducts, hoses or tubes that are not part of the supporting structure.

The interior space is preferably also closed off at the bottom, preferably by a floor that is arranged at a distance from the panel elements and preferably at least essentially parallel to them (the slight inclination possible due to the overlapping arrangement of the panel elements is still considered to be essentially parallel). The floor can, for example, be formed at least in part by one or more insulating panels. If the above-mentioned cross tubes are provided, insulation panels can preferably be arranged between the cross tubes, whereby it is possible for the insulation panels to overlap the cross tubes completely or partially.

Preferably, openings are provided that feed air into the interior space or discharge air from it. The openings can, for example, be formed as holes in the floor of the interior space. Inlets and outlets are preferably arranged at a distance from each other, preferably at a distance in the longitudinal direction. The distance between the inlet and outlet preferably corresponds to at least 50% of the length of a panel element, further preferably at least the length of a panel element, and is particularly preferably greater than the length of a panel element.

The openings are preferably connected to ducts for guiding the air flow, e.g. hoses, tubes, air ducts or similar.

When photovoltaic modules are arranged in the interior space, it is preferable that areas through which air can flow are formed both above and below the photovoltaic modules, i.e. the photovoltaic modules are preferably spaced from a cover arranged above and from a floor arranged below. In this way, a desired operating temperature range of the photovoltaic modules can be maintained by air flowing around the modules. The photovoltaic modules can preferably be arranged on spacers in the interior space, whereby the spacers can further preferably be attached to the cross tubes.

The method according to the invention provides for the manufacturing of the roof structure described above. This comprises the steps of forming the supporting gutters from supporting gutter sections arranged aligned and overlapping with each other, arrangement of the supporting gutters on the roof surface and overlapping arrangement of the panel elements on the support areas of the supporting gutter sections, wherein the panel elements can be photovoltaic modules and/or transparent covers and optionally photovoltaic modules can still be arranged below the panel elements. The steps mentioned can be carried out in different sequences, preferably photovoltaic modules are first attached to a roof surface and then individual supporting gutter sections and from these the supporting gutters are formed by overlapping attachment of further supporting gutter sections before the panel elements are placed on the support areas.

### BRIEF DESCRIPTION OF THE DRAWINGS

In the following, embodiments of the invention are described in more detail with reference to drawings, wherein

FIG. 1 shows a first embodiment of a roof structure in a schematic side view of the roof region of a building with a pitched roof;

FIG. 2 shows a perspective view of part of the roof structure from FIG. 1;

FIG. 3 shows a side view of part of the roof structure from FIGS. 1, 2;

FIG. 4 shows a view of the section through the roof structure along the section line A . . . A in FIG. 2;

FIG. 5 shows a view of the section through the roof structure along the section line B . . . B in FIG. 2;

FIG. 6 shows a view of the section through the roof structure along the section line C . . . C in FIG. 2;

FIG. 7 shows Elements of the roof structure from FIG. 2-6 in an exploded view;

FIG. 8 shows a second embodiment of a roof structure on a building with a pitched roof in a schematic side view;

FIG. 9 shows a side view of part of the roof structure from FIG. 8;

FIG. 10 shows an exploded view of the roof structure shown in FIGS. 8, 9;

FIG. 11 shows a perspective view of parts of the roof structure as shown in FIGS. 8-10;

FIG. 12 shows a view of the section along line D . . . D in FIG. 11;

FIG. 13 shows a lateral view of the overlapping of two supporting gutter sections in the second embodiment according to FIGS. 8-12;

FIGS. 14a, 14b show a supporting gutter section of the second embodiment according to FIGS. 8-13 in plan view and front view;

FIG. 14c shows a perspective view of an insert of the supporting gutter section according to FIGS. 14a, 14b;

FIG. 15 shows a perspective view of a retainer of the second embodiment according to FIG. 8-14c;

FIG. 16 shows a Perspective view of two interlocking retainers of the second embodiment according to FIGS. 8-15.

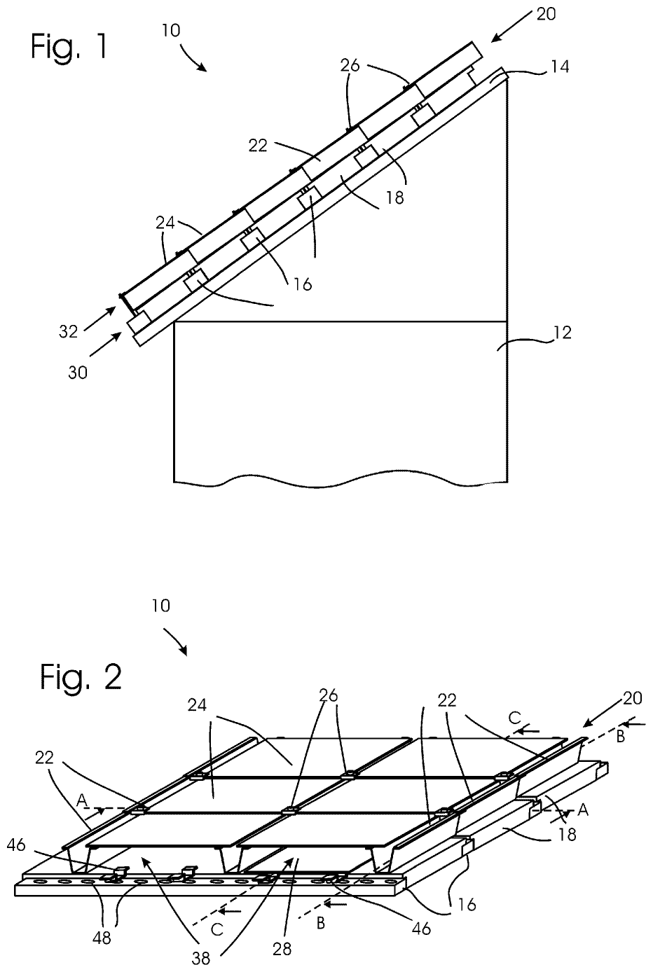

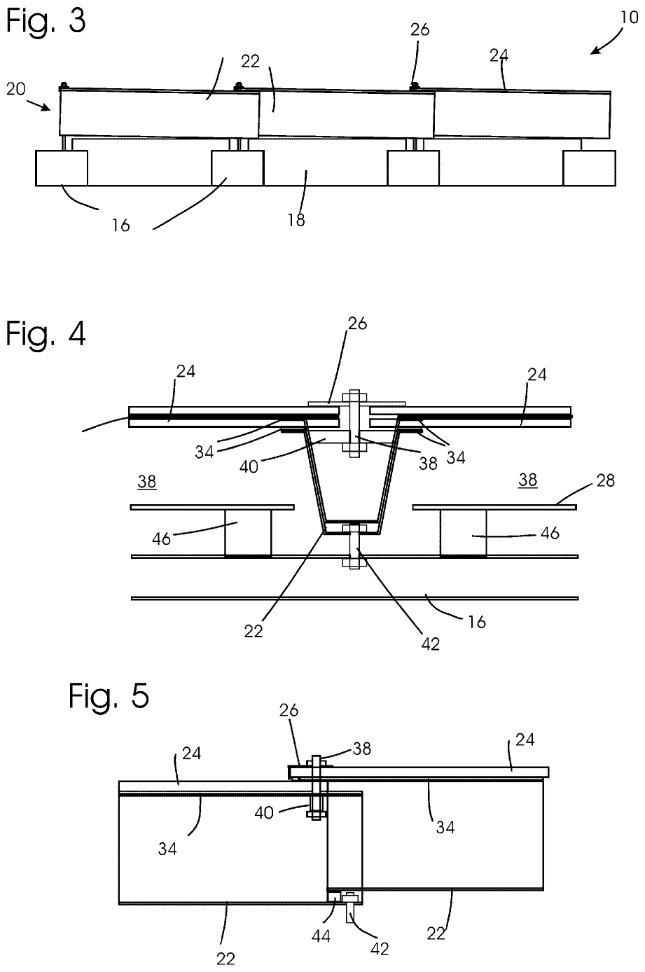

FIGS. 1-7 show a first embodiment of a roof structure 10.

### DETAILED DESCRIPTION OF EMBODIMENTS

FIG. 1 shows a schematic view of the roof structure 10 according to the first embodiment on a pitched roof of a building 12. Here and in the following, the illustration concentrates on the outer roof structure, i.e. in particular the roofing, independently of the supporting roof structure, of which only one of a plurality of roof beams 14 is shown here by way of example.

The roof structure 10 comprises a lower structure 30 with cross tubes 16 and insulation panels 18 arranged therebetween and an upper structure 32 fixed thereon with supporting gutters 20 (of which one supporting gutter 20 is shown in side view in FIG. 1) and panel elements 24 resting thereon.

The cross tubes 16 run perpendicular to the drawing area of FIG. 1 in a direction, which is referred to below as the transverse direction. A plurality of cross tubes 16 are arranged parallel to one another and are regularly spaced apart within the roof surface in a direction which is referred to here as the longitudinal direction.

As a person skilled in the art will readily recognize, the roof structure 10 shown is a regularly repeating structure with a plurality of cross tubes 16, supporting gutters 20 and panel elements 24. In the drawings, only parts of the repeating structure are shown, for example in FIG. 1 six parallel cross tubes 16 and in FIG. 2 four parallel cross tubes 16 as well as three supporting gutters 20 and two rows of panel elements 24 arranged one behind the other in the longitudinal direction. In specific embodiments, this arrangement is continued and repeated in each case to the extent that it corresponds to the dimensions of the roof surface. Furthermore, for better visibility of the elements, no lateral terminations are shown in the drawings, although these are preferably present in a complete roof structure 10 in the form of circumferential covers.

As can be seen in particular from FIG. 2, each of the supporting gutters 20 is formed from supporting gutter sections 22 aligned in the longitudinal direction. Each supporting gutter section 22 is formed in one piece from a profile of folded sheet metal approximately 80 cm long in the preferred example and has a trapezoidal cross-sectional shape throughout (which can also be seen from FIG. 4) with a flat base and two side walls projecting obliquely therefrom at opposite angles, from which support areas 34 project outwards at the upper edge. As can also be seen from FIG. 4, FIG. 5, the supporting gutter sections 22 are arranged overlapping and nested in one another at their end regions over a length of approximately 7 cm in the preferred example.

The panel elements 24 are placed on the support areas 34, with a flexible seal interposed (not shown in the drawings). In the preferred embodiment shown, the panel elements 24 are flat, transparent glass panes. They form the upper end of the roof structure 10. The panel elements 24 bridge two adjacent supporting gutters 20, each resting on the opposite support areas 34. Between the supporting gutters 20 and below the panel elements 24, enclosed interior spaces 36 are thus formed, which are sealed off from the outside in a wind and rainproof manner.

The panel elements 24 are arranged to overlap one another in the longitudinal direction (FIG. 5), wherein, as shown in FIG. 2, the panel element 24 arranged higher in the direction of the roof slope covers the panel element 24 arranged below it over an overlap area of a few centimeters. Flexible seals are arranged between the panel elements 24 in the overlapping area.

The nested, partially overlapping arrangement of the supporting gutter sections 22 allows an overlapping arrangement of the panel elements 24 resting thereon with full-surface contact on the support areas 34. The panel elements 24 are thus supported over their entire length (in the longitudinal direction) and a sealing support is made possible.

The panel elements are fastened to the supporting gutters 20 by retainers 26. As can be seen in particular from FIGS. 4, 5, the retainers 26 are folded plates which rest on the upper side of the panel elements 24 and grip around their final edge, which points downwards in the longitudinal direction in the direction of the roof slope. The retainers 26 are each arranged in the area of the lower corners of the panel elements 24 in the longitudinal direction. Intermediate layers of a flexible plastic sealing material are placed between the retainers 26 and the panel elements 24 in order to prevent damage to the panel elements due to mechanical stresses.

The retainers 26 are held by retainer bolts 38, which are attached by screw nuts to crossbars 40, which are attached in the supporting gutter sections 22 between the side walls. The crossbars 40 are each fixed in the region of the rear ends of the supporting gutter sections 22, but at some distance from the rear end, so that the retainers 26 and retainer bolts 38 are each arranged adjacent to the regions of overlap of the end portions of the supporting gutter sections 22. As shown in FIG. 5 as an example for a retainer 26 with retainer bolt 38 and crossbar 40, only a small distance in the longitudinal direction of the supporting gutter sections 22 remains between the retainer bolt 38 and the upper supporting gutter section 22 of the overlap. In the transverse direction, as shown in FIG. 4, the retainer bolts 38 are centered within the supporting gutters 20 and thus engage through the gap formed by two panel elements 24 adjacent in the transverse direction. The retainers 26 engage over the gap and thus fix two panel elements 24 in each case.

The supporting gutter sections 22 are each drilled through at their rear section in the direction of the roof slope in the area of the floor and fastened there to the cross tubes 16 by means of fastening bolts 42. As can be seen in particular from FIG. 5, the fastening bolts 42 are in each case arranged in the region of the overlap of the supporting gutter sections 22, so that the bore in the base of the lower supporting gutter section 22 is covered by the upper supporting gutter section 22 arranged above it. Seals 44 are arranged between the supporting gutter sections 22 in the overlapping area. Thus, the fastening bolts 42 provide a permanent fastening of the supporting gutters 20 while at the same time maintaining the tightness. In the area of each overlap, the lower supporting gutter section 22 is thus secured by screwing it to a supporting tube 16 and in turn secures the panel elements 24 resting on it via the fixed crossbar 40.

The roof structure 10 is sealed against weather influences by the elements described and, where necessary, any seals arranged between them. Rainwater is drained away on the panel elements 24 and within the supporting gutter 20 in the direction of the roof slope.

The interior spaces 36 are bounded in the transverse direction by the walls of the supporting gutter sections 22, upwards by the panel elements 24 and downwards by a floor formed by the upper sides of the insulation panels 18 and the cross tubes 16. In the longitudinal direction, the interior spaces 36 are continuous below the individual panel elements 24, but closed and sealed at the ends (not shown).

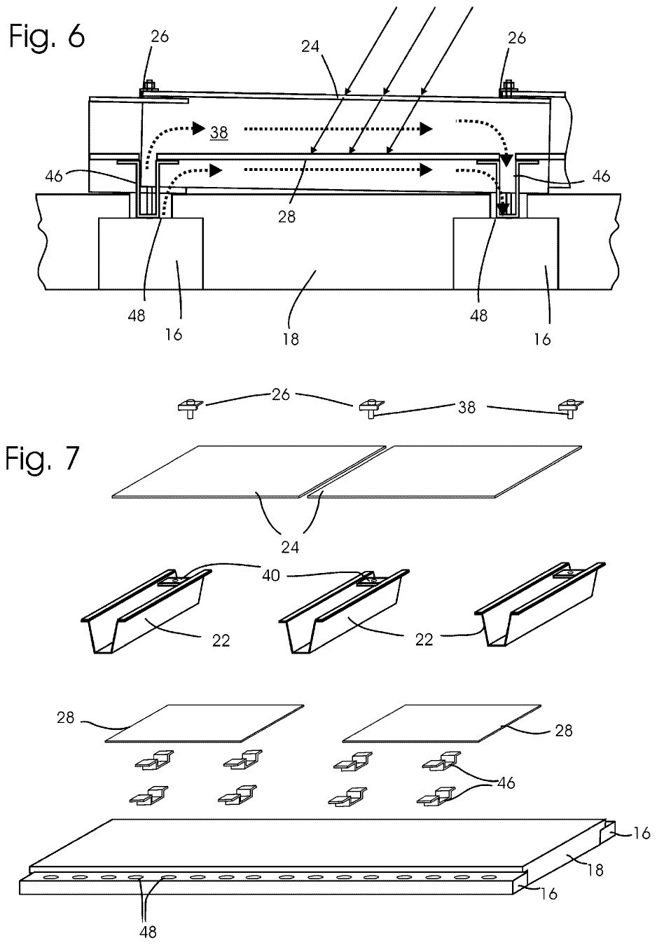

In each of the interior spaces 38, panel-shaped photovoltaic modules 28 are arranged at a distance between the bottom and the underside of the panel elements 24 (see, for example, FIG. 6). The photovoltaic modules 28 are attached to the cross tubes 16 with spacers 46. Areas through which air can flow are thus formed above and below the photovoltaic modules 28.

Openings 48 are arranged on the upper side of the cross tubes 16, which form connections to the interior spaces 38. Air can thus be fed into the interior spaces 38 through the cross tubes 16 and discharged therefrom. Preferably, the cross tubes 16 are connected to air-conveying fans in such a way that air is alternately supplied and discharged through cross tubes 16 arranged next to each other, so that, as indicated by dotted arrows in FIG. 6, an air flow results within the interior spaces 38, which flows around the photovoltaic modules 28 on the upper and lower sides.

When solar radiation is present, the sunlight passes through the transparent panel elements 24 into the interior space 38 and onto the photovoltaic module 28, as shown in FIG. 6. This generates electrical power, which is dissipated through electrical lines not shown here. This heats up the photovoltaic module 28 and the air in the interior space 38. Due to the air guidance described above, warm air is dissipated through cross tubes 16 and can be used, for example, for heating or for generating electricity. The air guidance thus dissipates heat from the interior space 38, thus enabling the photovoltaic module 28 not to heat up excessively to a temperature at which efficiency would be too severely impaired.

Due to the roof structure 10, a very efficient use of solar radiation is possible with a simple design, good sealing and few components. Air guidance allows the heat generated to be used, while at the same time ensuring that the photovoltaic modules 28 can operate in a favorable temperature range.

The roof structure 10 is easy to assemble, mechanically stable and also inexpensive to service. Various procedures with different sequences of construction steps are possible. Preferably, the cross tubes 16 are first attached to the supporting roof structure in the transverse direction and the insulation panels 18 are attached between them, then the photovoltaic modules 28 are attached to the spacers 46 and electrically connected (not shown). The supporting gutters 20 are then assembled piece by piece from the supporting gutter sections 22 and screwed onto the cross tubes 16. Alternatively, the supporting gutters 20 can also be assembled and fastened to the cross tubes 16 before the photovoltaic modules are mounted. Finally, the panel elements 24 are placed overlapping on the supporting gutters 20 and secured by the retainers 26.

In the event of servicing, access to the interior space 36 can be easily gained by releasing the retainers 26 and lifting panel elements 24, e.g. to replace photovoltaic modules 28.

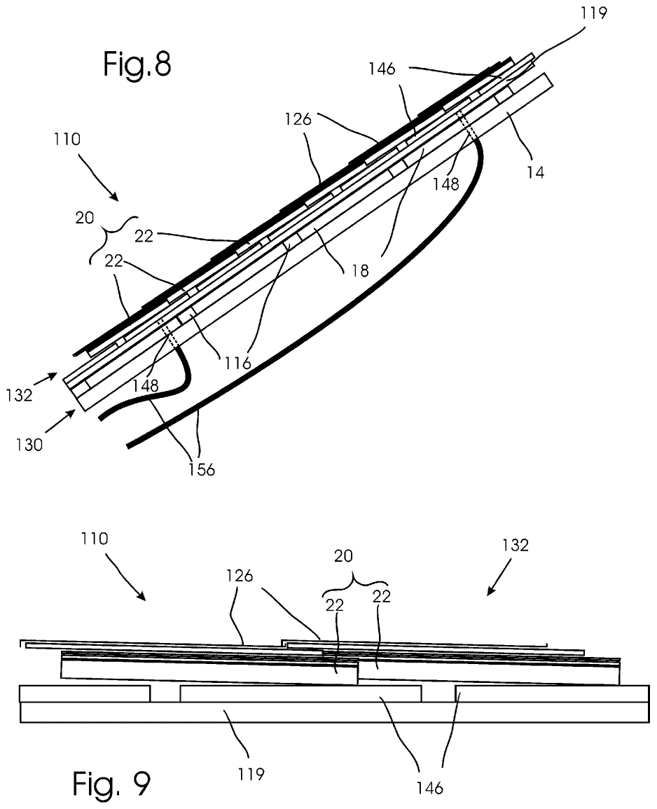

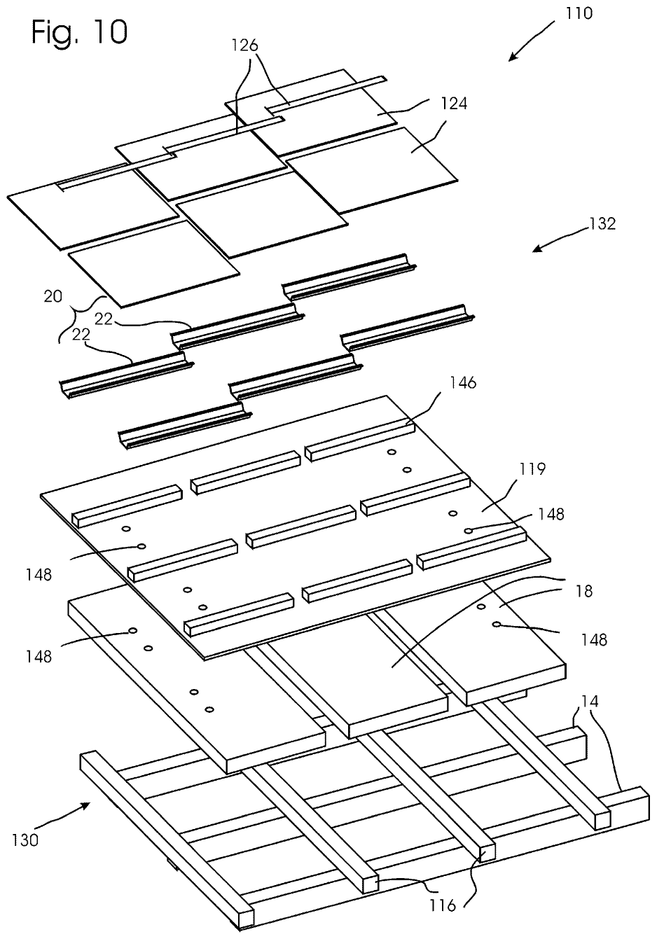

FIGS. 8-15 show a second, preferred embodiment. The roof structure 110 according to the second embodiments corresponds in many elements of the structure as well as in many details to the roof structure 10 according to the first embodiment. In the following, particular reference is made to the differences between the embodiments. Identical elements are provided with identical reference signs.

As shown in FIGS. 8-10, the roof structure 110 comprises a lower structure 130 with roof beams 14 and crossbeams 116 and insulation panels 18 arranged therebetween, on which a closed roof plate 119 is applied. The roof beams 14 run parallel in the longitudinal direction, i.e. following the roof slope, while the crossbeams 116 run transversely parallel to each other in the transverse direction. The roof plate 119 is preferably formed from panels with water-repellent properties that are interlocked by tongue and groove, preferably as a possible second water-bearing layer.

An upper structure 132 is attached to the lower structure 130 with spacer bars 146, supporting gutters 20 attached thereto and panel elements 124 with spacers 126 resting thereon. In the illustrations of the second embodiment, as in the first embodiment, only parts of the regularly repeating structure are shown in each case without edge terminations.

As in the first embodiment, in the second embodiment each of the supporting gutters 20 is formed from supporting gutter sections 22 aligned in the longitudinal direction. The supporting gutter sections are shown separately in FIGS. 14a, 14b. In the embodiment example shown, each supporting gutter section is formed, for example, from a sheet metal with a thickness of 0.8-1.4 mm, preferably 1 mm. The trapezoidal profile has, for example, a height of approx. 35 mm, lower inner width of approx. 30 mm, upper inner width of approx. 50 mm with sealing strips fen 123 on flange sections of, for example, 10 mm width. The trapezoidal shape comprises angle folds of, for example, 108° each. The outer angle folds form contact surfaces 34 with glued-on flexible sealing strips 123.

The bottom of the supporting gutter section 22 is closed except for a bore at one end. Two inserts 50 with threaded nuts (FIG. 14c) are inserted and welded into the profile of the supporting gutter section 22.

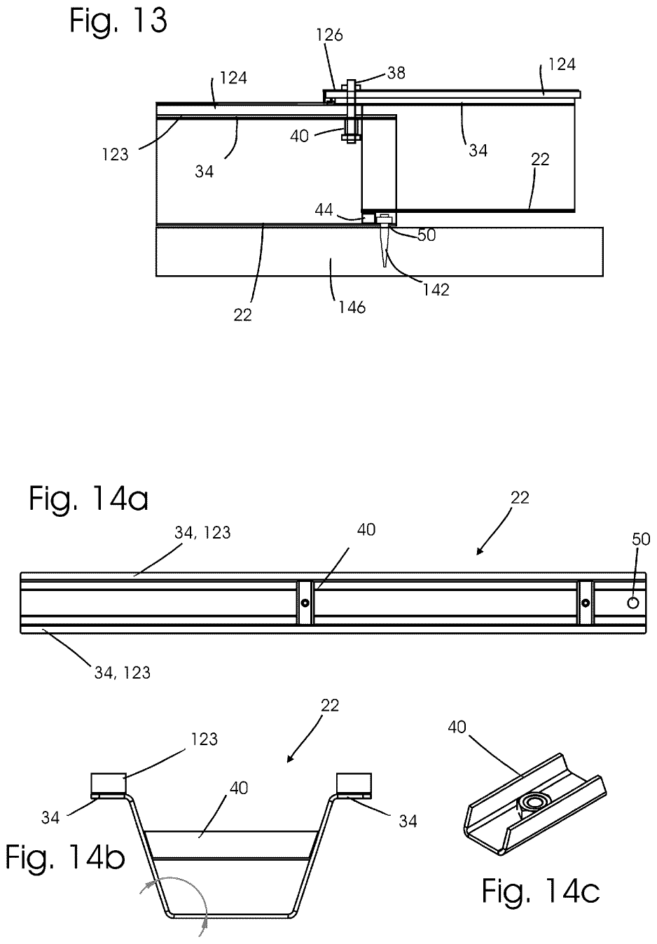

In the roof structure 110, the supporting gutter sections 22 are arranged in an interlocking, i.e. nested, manner with a partial overlap, as in the first embodiment. Thereby, as shown in FIG. 13, the pierced end of the respective lower supporting gutter section 22 is covered by the end of the supporting gutter section arranged above it.

Panel elements 124 are placed on the sealing strips 123 of the supporting surfaces 34 of the supporting gutter sections 22, the panel elements 124 also being arranged overlapping one another in accordance with the overlapping arrangement of the supporting gutter sections 22. Flexible seals (not shown) are arranged between overlapping panel elements.

Unlike in the first embodiment, in the second embodiment the panel elements 124 are not transparent glass panes, but rather flat photovoltaic modules. Thus, in this embodiment, the photovoltaic modules 124 themselves form the upper end of the roof structure 110.

As in the first embodiment, the panel elements 124 arranged in each case between two adjacent supporting gutters 20 thus cover closed interior spaces 36 which are closed off from the outside in a windproof and rainproof manner. The interior spaces 36 are each bounded laterally in the transverse direction by the supporting gutter sections 22 and spacer bars 146, upwards by the panel elements 124 and downwards by the roof plate 119. In the longitudinal direction, the interior spaces are continuous, for example extending from the roof ridge to the lower end, although subdivisions are also possible.

Due to the nested, partially overlapping arrangement of the supporting gutter sections 22, the panel elements 124 resting thereon, which are also arranged in an overlapping manner, are aligned parallel thereto, so that uniform contact is provided on the support areas 34.

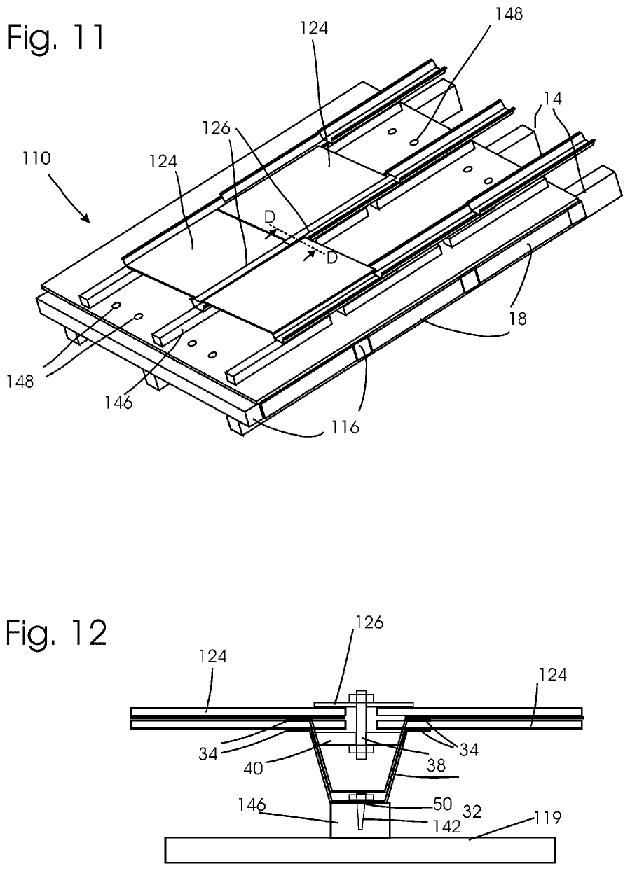

As in the first embodiment, in the second embodiment the panel elements 124 are fixed to the supporting gutters 20 by retainers 126. Unlike in the first embodiment, the retainers 126 are elongate strips which cover the panel elements 124 over their entire length, as can be seen in particular from FIG. 11 (only two retainers 126 are shown here for clarity).

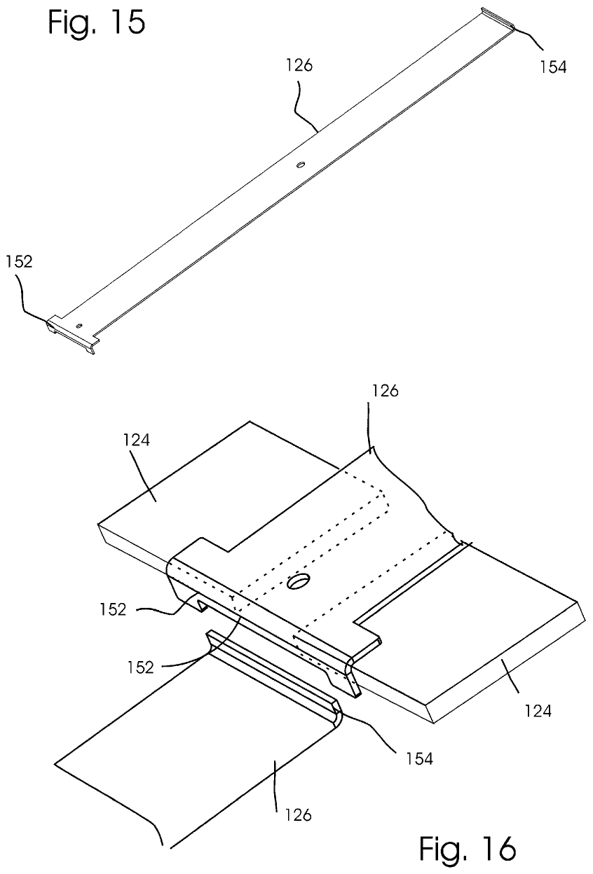

Retainers 126 are shown in more detail in FIGS. 15, 16. These are elongated strips of sheet metal, in which a downwardly directed fold 152 is formed at a lower end and an upwardly directed fold 154 is formed at the upper end. As can be seen from FIG. 16, the lower end of the retainer 126 is widened and the lower fold 152 has a central recess of the width of the upper fold 152.

The retainers 126 are each placed on the panel elements 124 in such a way that they cover two laterally adjacent panel elements 124 (FIG. 16). Thereby, retainers 126 arranged in alignment with one another interlock by the lower fold 152 of the higher arranged retainer 126 engaging over the upper fold 154 of the retainer 126 arranged below it. At the same time, the lower fold 152 engages around the panel elements 124 and thus secures them against slipping. Here, too, no direct contact of the retainers 126 with the panel elements 124 is formed, but an intermediate layer is arranged therebetween (not shown).

As in the first embodiment, the retainers 126 are held in place by retainer bolts 38 which are screwed to the crossbars 40 of the underlying supporting gutter sections 22 by means of the screw nuts.

The supporting gutter sections 22 themselves are screwed to the spacer bars 146 below by means of screws 142, using the screw hole 50 (FIG. 13). As in the first embodiment, the overlapping and sealing 44 ensure the tightness.

As in the first embodiment, tightness of the roof structure 110 is ensured, with rainwater being drained away on the panel elements 124 and in the supporting gutters 20. In the event of minor leaks at the seals between them, any water that may penetrate into the interior space 36 can be drained away on the roof plate 119 in the direction of the roof slope.

The interior spaces 36 formed between the supporting gutters 22 and below the panel elements 124 (photovoltaic modules) each represent areas through which air can flow. Air is introduced into the intermediate spaces 36 through hoses 156 and holes 148 penetrating the roof plate 119 and the insulation panels 18 and is drawn out again at another point (see, for example, FIG. 11). The air thus flowing in the interior spaces 36 is in contact with the underside of the panel elements 124 (photovoltaic elements), so that these can be cooled by the air flow. As in the first embodiment, this allows the heat generated to be utilized while ensuring that the photovoltaic modules 124 can operate within a favorable temperature range.

As shown in FIG. 8, the inlet and outlet are preferably spaced apart in the longitudinal direction, particularly preferably at a distance greater than the length of a panel element 124 in the longitudinal direction.

While two separate embodiments are described above, the invention can be implemented in different ways. For example, individual features or concepts are interchangeable between the embodiments, e.g. the air guidance by means of cross tubes or by means of hoses/boreholes, the design of the retainers either over the entire length of the panel elements or only at their corners, or the design of the panel elements either as photovoltaic modules themselves or as covers for such modules.

List of reference symbols

| | | | |
|---|---|---|---|
| 10, 110 | roof structure | 40 | crossbar |
| 12 | building | 42. 142 | fastening bolt/screw |
| 14 | roof beam | 44 | seal between supporting gutter |
| | | | sections |
| 16 | cross tube | 46 | spacers for photovoltaic |
| | | | modules |
| 116 | crossbeam | 146 | spacer bar |
| 18 | insulation panel | 48, 148 | openings for air supply |
| 119 | roof plate | 50 | screw hole |
| 20 | supporting gutter | 152 | lower fold of the retainers |
| 22 | supporting gutter | 154 | upper fold of the retainers |
| | section | | |
| 123 | sealing strips on | 156 | hoses |
| | supporting gutter | | |
| | sections | | |
| 24 | panel element | | |
| 26, 126 | retainer | | |
| 28 | photovoltaic | | |
| | module | | |
| 30, 130 | lower structure | | |
| 32 | upper structure | | |
| 34 | support areas | | |
| 36 | interior space | | |
| 38 | retainer bolt | | |

1. Roof structure, with
a plurality of parallel supporting gutters, each formed from aligned supporting gutter sections, wherein ends of the supporting gutter sections are arranged to overlap one another,
wherein panel elements are each arranged between two supporting gutters and rest on support areas of the supporting gutter sections,
wherein the panel elements are arranged overlapping in the longitudinal direction of the supporting gutters,
and wherein the panel elements are transparent covers and photovoltaic modules are arranged below the panel elements, and/or wherein the panel elements are photovoltaic modules.

2. Roof structure according to claim 1, in which
retainers are arranged on the panel elements and connected to the supporting gutters.

3. Roof structure according to claim 2, in which
the retainers are elongate in shape and extend in the longitudinal direction of the panel elements.

4. Roof structure according to claim 3, in which
the retainers have an upper fold at an upper end and a lower fold at a lower end,
wherein the upper and lower folds of aligned retainers interlock.

5. Roof structure according to claim 1, in which
the supporting gutter sections have a trapezoidal cross-sectional shape.

6. Roof structure according to claim 1, in which
the panel elements sealingly terminate with the support areas of the supporting gutter sections, so that an interior space sealed with respect to the upper side of the panel elements is formed between the supporting gutters and below the panel elements.

7. Roof structure according to claim 6, in which
openings are provided for the supply or removal of air from the interior space.

8. Roof structure according to claim 7, in which
the supporting gutters are mounted on cross tubes,
wherein the openings for the supply or removal of air are provided on the upper side of the cross tubes.

9. Roof structure according to claim 7, in which
the openings for the supply or removal of air are connected to ducts for guiding the air flow.

10. Roof structure according to claim 6, wherein
the interior space is closed off by a floor at a distance from the panel elements.

11. Roof structure according to claim 6, wherein
photovoltaic modules are arranged in the interior space,
wherein areas through which air can flow are formed above and below the photovoltaic modules.

12. Roof structure according claim 1, in which
the supporting gutter sections have outer folds, the upper sides of the folds forming the support areas.

13. Roof structure according to claim 1, in which
between the panel elements and the contact surfaces and/or
between overlapping panel elements and/or
between overlapping supporting gutter sections seals are arranged.

14. Method for producing a roof structure with photovoltaic modules, in which
a plurality of parallel supporting gutters are formed on a roof surface from aligned supporting gutter sections, wherein ends of the supporting gutter sections are arranged to overlap one another,
panel elements are each arranged between two supporting gutters in such a way that they rest on support areas of the supporting gutter sections,
and wherein the panel elements are arranged overlapping in the longitudinal direction of the supporting gutters, and wherein the panel elements are transparent covers and photovoltaic modules are arranged below the panel elements, and/or wherein the panel elements are photovoltaic modules.
